(19) United States
(12) Patent Application Publication
(10) Pub. No.: US 2025/0349326 A1
(43) Pub. Date: Nov. 13, 2025

(54) SEMICONDUCTOR MEMORY DEVICES WITH FLYING BIT LINES AND METHODS OF MANUFACTURING THEREOF

(71) Applicant: Taiwan Semiconductor Manufacturing Company, Ltd., Hsinchu (TW)

(72) Inventors: Yi-Hsin Nien, Hsinchu (TW); Hidehiro Fujiwara, Hsinchu (TW); Chih-Yu Lin, Hsinchu (TW); Yen-Huei CHEN, Hsinchu (TW)

(73) Assignee: Taiwan Semiconductor Manufacturing Company, Ltd., Hsinchu (TW)

(21) Appl. No.: 19/275,332

(22) Filed: Jul. 21, 2025

Related U.S. Application Data
(63) Continuation of application No. 18/490,922, filed on Oct. 20, 2023.
(60) Provisional application No. 63/512,359, filed on Jul. 7, 2023.
(60) Provisional application No. 63/517,781, filed on Aug. 4, 2023.

(51) Int. Cl. G11C 5/06; G11C 11/418

(52) U.S. Cl. CPC G11C 5/063; G11C 11/418

(57) ABSTRACT

A memory device includes a first memory array comprising first memory cells; a second memory array comprising second memory cells; a third memory array comprising third memory cells, the second memory array interposed between the first memory array and the third memory array along a lateral direction; a first bit line segment extending along the lateral direction and coupled to each of the first memory cells; a second bit line segment extending along the lateral direction and coupled to each of the second memory cells; and a third bit line segment extending along the lateral direction and coupled to each of the third memory cells. The first bit line segment is formed in a first metallization layer, the second bit line segment is formed in a second metallization layer, and the third bit line segment is formed in a third metallization layer.

### CROSS-REFERENCE TO RELATED APPLICATION

This application is a continuation of U.S. patent application Ser. No. 18/490,922, filed Oct. 20, 2023, which claims the benefit of U.S. Provisional Patent Application No. 63/512,359, filed Jul. 7, 2023, and U.S. Provisional Patent Application No. 63/517,781, filed Aug. 4, 2023, all of which are incorporated herein by reference in their entireties and for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device, in accordance with some embodiments.

FIG. 2 illustrates a schematic diagram of a memory cell, in accordance with some embodiments.

FIG. 3 illustrates a schematic block diagram of an implementation of the memory device of FIG. 1, in accordance with some embodiments.

FIG. 4 illustrates a perspective view of a semiconductor device including a number of metallization layers formed above a substrate, in accordance with some embodiments.

FIG. 5 illustrates an example cross-sectional view of the implementation of the memory device shown in FIG. 3, in accordance with some embodiments.

FIG. 6 illustrates another example cross-sectional view of the implementation of the memory device shown in FIG. 3, in accordance with some embodiments.

FIG. 7 illustrates a schematic block diagram of another implementation of the memory device of FIG. 1, in accordance with some embodiments.

FIG. 8 illustrates a schematic block diagram of yet another implementation of the memory device of FIG. 1, in accordance with some embodiments.

FIG. 9 illustrates an example top view of the implementation of the memory device shown in FIG. 8, in accordance with some embodiments.

FIG. 10 illustrates an example cross-sectional view of the implementation of the memory device shown in FIG. 8, in accordance with some embodiments.

FIG. 11 illustrates an example flow chart of a method for forming a memory device, in accordance with some embodiments.

FIG. 12 illustrates an example flow chart of another method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor memory device is an electronic data storage device implemented on a semiconductor-based integrated circuit. A semiconductor memory device has various types, and has faster access times than other data storage technologies. For example, a byte of data can often be written to or read from a semiconductor memory device within a few nanoseconds, while access times for rotating storage, such as hard disks, is in the range of milliseconds. For these reasons, among others, the semiconductor memory device is used as a primary storage mechanism for computers to hold data that the computers are currently working on, among other uses.

Static Random Access Memory (SRAM) is a type of a semiconductor memory device that stores data in the form of bits using bistable circuitry without the need for refreshing. An SRAM cell may be referred to as a bit cell because it stores a bit of information. A memory array generally include multiple bit cells arranged in rows and columns. Each bit cell in a memory array may include connections to a power supply voltage and to a reference voltage. Bit lines (BLs) may be used for accessing a bit cell with a word line (WL) controlling connections to the BLs. A WL may be coupled to a corresponding set of the bit cells that are arranged in a row of a memory array with different WLs provided for respective rows, and a BL may be coupled to a corresponding set of the bit cells that are arranged in a column of a memory array with different BLs provided for respective columns.

A memory bank, including at least one memory array, often has memory cells in the range of about 128 rows to about 512 rows. With the trend of continuously scaling-down feature sizes, a memory bank can include an increasing number of rows accordingly. However, the increased number of rows typically leads to long BLs, and hence high loads on the BLs. The high loads on the BLs may, in turn, lead to high minimum read voltages and high minimum write voltages on the BLs. Read voltages and write voltages below the high minimum read voltages and the high minimum write voltages lead to instability while reading from and writing to the memory cells. Further, the high minimum read voltages and the high minimum write voltages may, in turn, lead to high dynamic power consumption.

One solution to mitigate the effects of long BLs is to use smaller memory banks. For example, one large memory bank with 128 rows can be replaced with two small memory banks, each of which has 64 rows. However, increasing the number of banks increases the area used by the memory cells, which may increase costs. In this regard, another solution has been proposed to break the long BL into multiple (e.g., 2) segments, each of which is operatively coupled to a respective portion of the memory bank. For example, a long BL is separated into a first BL segment and a second BL segment, where a BL control circuit (e.g., driver) is coupled to a first (near) portion and a second (far) portion of the memory bank through the first and second BL segments, respectively. Further, the BL control circuit utilizes another BL, formed in a metallization layer higher than the first and second BL segments, to couple itself to the second BL segment.

Although the effect of high loads for a long BL can be mitigated through the separated BL segments, a spacing between adjacent BLs (e.g., across different columns) is becoming smaller. As technology improves and feature sizes become smaller, adjacent BLs will become even more closely spaced. However, this close spacing results in a significant amount of capacitive coupling. The capacitive coupling may, in turn, lead to slow read and write times, and may further lead to a degradation of signal-to-noise margins. Thus, the existing memory device has not entirely satisfactory in certain aspects.

The present disclosure provides various embodiments of a memory device that has a plural number of BLs, each of which is separated into several BL segments, and the adjacent ones of those BLs are laterally spaced with a larger spacing when compared to the existing memory devices. Thus, at least one the issues of high load on a long BL or the issues of capacitive coupling between adjacent BLs can be resolved.

In one non-limiting aspect of the present disclosure, each BL of the disclosed memory device disposed in a first metallization layer can be separated into three or more BL segments, e.g., a first BL segment, second BL segment, and a third BL segment. A BL controller of the memory device can be operatively coupled to a first portion of a corresponding memory bank (sometimes referred to as a bottom memory array) through the first BL segment. The BL controller can be operatively coupled to a second portion of the memory bank (sometimes referred to as a middle memory array) through the second BL segment and further through another (e.g., fly) BL disposed in a second metallization layer. A “fly BL,” as used herein, may refer to a BL that physically travels across a memory array (or memory portion), but is not operatively coupled to that memory array (portion). The BL controller of the memory device can be operatively coupled to a third portion of the memory bank (sometimes referred to as a top memory array) through the third BL segment and further through yet another fly BL disposed in a third metallization layer. By utilizing the third metallization layer (or separating one long BL into at least three segments), design constraints on the size of a memory array can be significantly reduced. For example, the load of each BL can be further reduced, which advantageously allows the memory array to include an increased number of rows while having its BLs immune from high loads.

In another non-limiting aspect of the present disclosure, each BL of the disclosed memory device disposed in a first metallization layer can be separated into two or more BL segments, e.g., a first BL segment and second BL segment. A BL controller of the memory device can be operatively coupled to a first portion of a corresponding memory bank (sometimes referred to as a bottom memory array) through the first BL segment, with a complementary first BL segment also disposed in the first metallization layer. The BL controller can be operatively coupled to a second portion of the memory bank (sometimes referred to as a top memory array) through the second BL segment, with a complementary second BL segment also disposed in the first metallization layer. Further, the memory device can include another (e.g., fly) BL disposed in a second metallization layer connecting the BL controller to the second BL segment, and yet another fly BL also disposed in the second metallization layer connecting the BL controller to the complementary second BL segment. Such two fly BLs may be disposed along the same column as the first to second BL segments and along the next adjacent column, respectively. Following this principle, two corresponding fly BLs for the next adjacent column can be formed along the same column as the first to second BL segments and along the next adjacent column, respectively, but in a third metallization layer. Design constraints on the BL segments (and/or other metal tracks), e.g., in the first metallization layer, can be significantly reduced. Accordingly, the capacitive coupling between the adjacent BLs in the first metallization layer can be advantageously reduced.

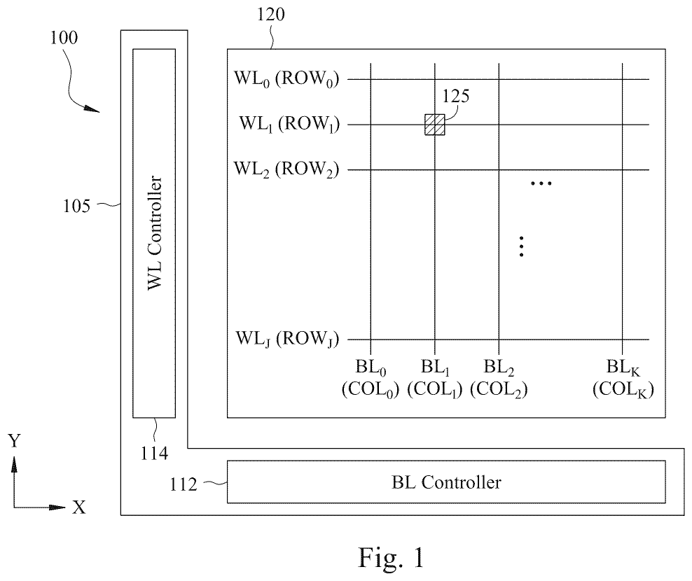

FIG. 1 illustrates a block diagram of a memory device 100, in accordance with some embodiments. As shown, the memory device 100 includes a memory controller 105 and a memory bank 120. The memory bank 120 may include a plurality of storage circuits or memory cells 125 arranged in two-or three-dimensional arrays. Each memory cell 125 may be coupled to a corresponding word line WL and a corresponding bit line BL (or a pair of BLs). The memory controller 105 may write data to or read data from the memory bank 120 according to electrical signals through word lines WL and bit lines BL. In other embodiments, the memory device 100 includes more, fewer, or different components than shown in FIG. 1.

The memory bank 120 is a hardware component that stores data. In one aspect, the memory bank 120 is embodied as a semiconductor memory device. The memory bank 120 includes a plurality of storage circuits or memory cells 125. The memory bank 120 includes word lines WL₀, WL₁ . . . WL_{J}, each extending in a first direction (e.g., the X-direction) and bit lines BL₀, BL₁ . . . BL_{K}, each extending in a second direction (e.g., the Y-direction). According to various embodiments of the present disclosure, the word lines WL₀ to WL_{J} may sometimes be referred to as rows, ROW₀ to ROW_{J}, respectively, and the bit lines BL0 to BLK may sometimes be referred to as columns, COL₀ to COL_{K}, respectively. The word lines WL and the bit lines BL may each be implemented as one or more metal or conductive tracks disposed in respective metallization layers. In one configuration, each memory cell 125 is coupled to a corresponding word line WL and a corresponding bit line BL, and can be operated according to voltages or currents through the corresponding word line WL and the corresponding bit line BL.

In various embodiments, each bit line BL includes bit lines BL, BLB (complementary to the BL) coupled to a group of the memory cells 125 disposed along the second direction (e.g., Y-direction), or along a corresponding one of the columns, COL₀ to COL_{K}. The bit lines BL, BLB may receive and/or provide differential signals. Each memory cell 125 may include a volatile memory, a non-volatile memory, or a combination of them. In some embodiments, each memory cell 125 can be embodied as a static random access memory (SRAM) cell, a dynamic random access memory (DRAM) cell or any other type of memory cell. For example, each memory cell 125 may be implemented as a resistive random access memory (RRAM) cell, phase-change random access memory (PCRAM) cell, or magnetoresistive random access memory (MRAM) cell. In some embodiments, the memory bank 120 includes additional lines (e.g., select lines, reference lines, reference control lines, power rails, etc.).

The memory controller 105 is a hardware component that controls operations of the memory bank 120. In some embodiments, the memory controller 105 includes at least a bit line controller 112 and a word line controller 114. The bit line controller 112 and the word line controller 114 may be embodied as logic circuits, analog circuits, or a combination of them. In one configuration, the word line controller 114 is a circuit that provides a voltage or current through one or more word lines WL of the memory bank 120, and the bit line controller 112 is a circuit that provides or senses a voltage or current through one or more bit lines BL of the memory bank 120. The bit line controller 112 may be coupled to bit lines BL of the memory bank 120, and the word line controller 114 may be coupled to word lines WL of the memory bank 120. In some embodiments, the memory controller 105 includes more, fewer, or different components than shown in FIG. 1.

For example, the memory controller 105 can include a timing controller configured to generate control signals to coordinate operations of the bit line controller 112 and the word line controller 114. In one approach, to write data to a memory cell 125, the timing controller may cause the word line controller 114 to apply a voltage or current to the memory cell 125 through a word line WL coupled to the memory cell 125 and cause the bit line controller 112 to apply a voltage or current corresponding to data to be stored to the memory cell 125 through a bit line BL coupled to the memory cell 125. In one approach, to read data from a memory cell 125, the timing controller may cause the word line controller 114 to apply a voltage or current to the memory cell 125 through a word line WL coupled to the memory cell 125 and cause the bit line controller 112 to sense a voltage or current corresponding to data stored by the memory cell 125 through a bit line BL coupled to the memory cell 125.

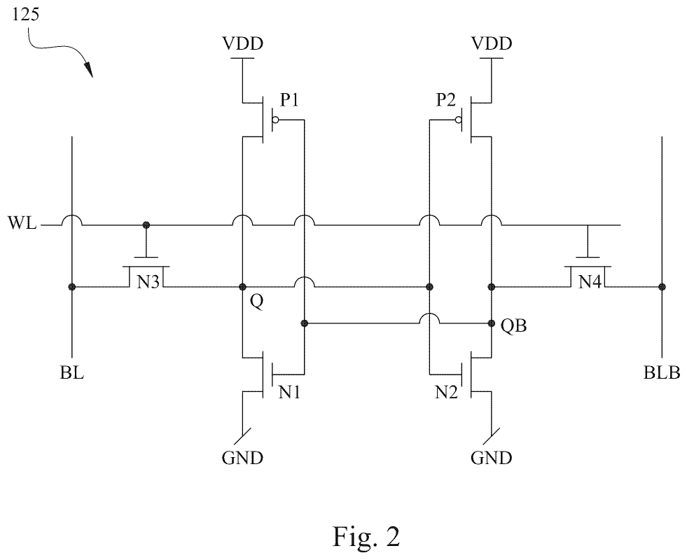

FIG. 2 illustrates a schematic diagram of the memory cell 125 that is implemented, for example, as an SRAM cell, in accordance with some embodiments. Hereinafter, the memory cell 125 may sometimes be referred to as SRAM cell 125. In some embodiments, the SRAM cell 125 includes N-type transistors N₁, N₂, N₃, N₄ and P-type transistors P₁, P₂. The N-type transistors N₁, N₂, N₃, N₄ may be planar N-type metal-oxide-semiconductor field-effect transistors (MOSFETs), N-type fin field-effect transistors (FinFETs), N-type gate-all-around field-effect transistors (GAA FETs), or various other N-type transistor structures. The P-type transistors P₁, P₂ may be P-type MOSFETs, P-type FinFETs, P-type gate-all-around field-effect transistors (GAA FETs), or various other P-type transistor structures. These components may operate together to store a data bit. In other embodiments, the SRAM cell 125 includes more, fewer, or different components than shown in FIG. 2.

In one configuration, the N-type transistors N₃, N₄ include gate electrodes coupled to a word line WL. In one configuration, a drain electrode of the N-type transistor N₃ is coupled to a bit line BL, and a source electrode of the N-type transistor N₃ is coupled to a port Q. In one configuration, a drain electrode of the N-type transistor N₄ is coupled to a bit line BLB, and a source electrode of the N-type transistor N₄ is coupled to a port QB. In one aspect, the N-type transistors N₃, N₄ operate as electrical switches. The N-type transistors N₃, N₄ may allow the bit line BL to electrically couple to or decouple from the port Q and allow the bit line BLB to electrically couple to or decouple from the port QB, according to a voltage applied to the word line WL. For example, according to a supply voltage VDD corresponding to a high state (or logic value ‘1’) applied to the word line WL, the N-type transistor N₃ is enabled to electrically couple the bit line BL to the port Q and the N-type transistor N₄ is enabled to electrically couple the bit line BLB to the port QB. For another example, according to a ground voltage GND corresponding to a low state (or logic value ‘0’) applied to the word line WL, the N-type transistor N₃ is disabled to electrically decouple the bit line BL from the port Q and the N-type transistor N₄ is disabled to electrically decouple the bit line BLB from the port QB.

In one configuration, the N-type transistor N₁ includes a source electrode coupled to a first supply voltage rail supplying the ground voltage GND, a gate electrode coupled to the port QB, and a drain electrode coupled to the port Q. In one configuration, the P-type transistor P₁ includes a source electrode coupled to a second supply voltage rail supplying the supply voltage VDD, a gate electrode coupled to the port QB, and a drain electrode coupled to the port Q. In one configuration, the N-type transistor N₂ includes a source electrode coupled to the first supply voltage rail supplying the ground voltage GND, a gate electrode coupled to the port Q, and a drain electrode coupled to the port QB. In one configuration, the P-type transistor P₂ includes a source electrode coupled to the second supply voltage rail supplying the supply voltage VDD, a gate electrode coupled to the port Q, and a drain electrode coupled to the port QB. In this configuration, the N-type transistor N₁ and the P-type transistor P₁ operate as an inverter, and the N-type transistor N₂ and the P-type transistor P₂ operate as an inverter, such that two inverters form cross-coupled inverters. In one aspect, the cross-coupled inverters may sense and amplify a difference in voltages at the ports Q, QB. When writing data, the cross-coupled inverters may sense voltages at the ports Q, QB provided through the N-type transistors N₃, N₄ and amplify a difference in voltages at the bit lines BL, BLB. For example, the cross-coupled inverters sense a voltage 0.5 V at the port Q and a voltage 0.4V at the port QB, and amplify a difference in the voltages at the ports Q, QB through a positive feedback (or a regenerative feedback) such that the voltage at the port Q becomes the supply voltage VDD (e.g., 1V) and the voltage at the port QB becomes the ground voltage GND (e.g. 0V). The amplified voltages at the ports Q, QB may be provided to the bit lines BL, BLB through the N-type transistors N₃, N₄, respectively for reading.

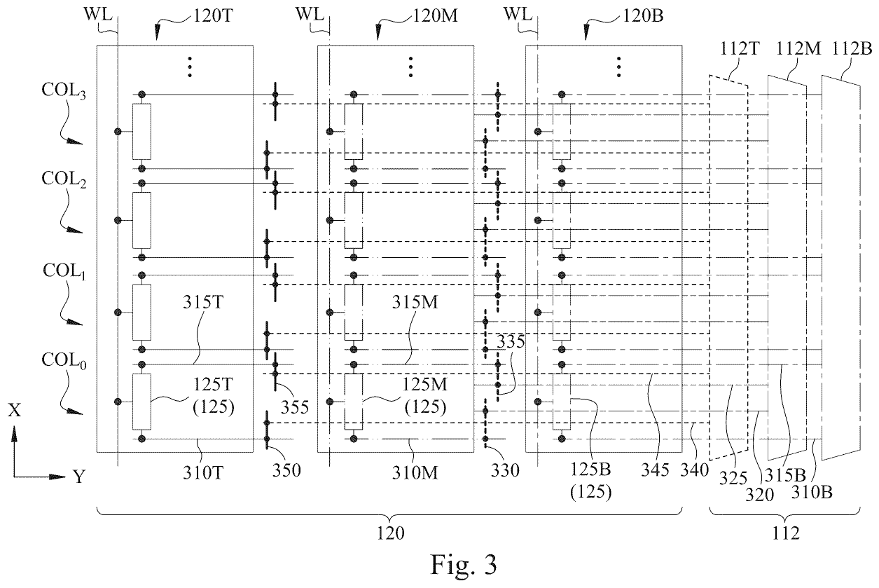

FIG. 3 illustrates a schematic block diagram of an implementation of a portion of the memory device 100, in accordance with some embodiments. For example, in FIG. 3, a portion of the memory bank 120 and a portion of the BL controller 112 are shown. Further, some of the BLs, and their operatively equivalent segments (e.g., each implemented as a metal track disposed in a corresponding metallization layer), are shown. It should be understood that the schematic block diagram of FIG. 3 is merely provided for illustrative purposes, and thus, the memory device 100 can be implemented as any of various other suitable configurations while remaining within the scope of the present disclosure.

As shown, the memory bank 120 may be operatively separated into three arrays, bottom array 120B, middle array 120M, and top array 120T. In one non-limiting example where the memory bank 120 has 1024 rows (e.g., 1024 WLs), the bottom array 120B may have 512 rows (e.g., 512 WLs), and each of the middle array 120M and top array 120T may have 256 rows (e.g., 256 WLs). However, other arrangement on the respective sizes of the separated arrays can be contemplated while remaining within the scope of the present disclosure. Corresponding to these three separated arrays, respectively, the BL controller 112 may include three sub-BL controllers, bottom BL controller 112B, middle BL controller 112M, and top BL controller 112T. In various embodiments, each of the sub-BL controllers 112B, 112M, and 112T may include at least a multiplexer configured to assert or otherwise select one or more BLs based on an address signal received. Further, each of the sub-BL controllers 112B, 112M, and 112T may be operatively coupled to the memory cells 125 of the corresponding array (e.g., applying a voltage signal to the memory cells 125) through a respective set of BLs.

Operatively, the sub-BL controllers, 112B, 112M, and 112T, are each coupled to the memory cells 125 of a corresponding separated array through a pair of BLs, BL and BLB, as shown in FIG. 1. In various embodiments, some of these operative BLs and BLBs, flying over one or more memory arrays, may each be physically implemented as one or more lateral segments (e.g., metal tracks) and one or more vertical connections (e.g., via structures) connected to one another, which will be discussed in further detail below.

As shown in FIG. 3, the memory bank 120 is separated into three arrays along the BL direction (e.g., the Y-direction), while retaining the arrangement along the WL direction (e.g., the X-direction). As such, it should be noted that each of the sub-BL controllers, 112B, 112M, and 112T, remains coupled to all of the BLs of the memory bank 120, but is just coupled to different subsets of the WLs of the memory bank 120. In the following discussion associated with FIG. 3, examples illustrating the arrangement between the sub-BL controllers, 112B, 112M, and 112T, and a representative column (e.g., COL₀) will be provided. The arrangements between the sub-BL controllers, 112B, 112M, and 112T, and others column (e.g., COL₁, COL₂, COL₃) will not be repeated.

For example, the bottom BL controller 112B can be operatively coupled to the memory cells 125 of the bottom array 120B (sometimes referred to as bottom memory cells 125B) in COL₀ through BL segments 310B and 315B; the middle BL controller 112M can be operatively coupled to the memory cells 125 of the middle array 120M (sometimes referred to as middle memory cells 125M) in COL₀ through BL segments 320 and 325, further through BL segments 330 and 335, and further through BL segments 310M and 315M; and the top BL controller 112T can be operatively coupled to the memory cells 125 of the top array 120T (sometimes referred to as top memory cells 125T) in COL₀ through BL segments 340 and 345, further through BL segments 350 and 355, and further through BL segments 310T and 315T. In some embodiments, the BL segments 310B and 315B can correspond to the portions of BL₀ and BLB₀ (i.e., BL/BLB in COL₀) operatively coupled to the memory cells 125B in COL₀, respectively; the BL segments (320, 330, and 310M) and (325, 335, and 315M) can correspond to the portions of BL₀ and BLB₀ (i.e., BL/BLB in COL₀) operatively coupled to the memory cells 125M in COL₀, respectively; and the BL segments (340, 350, and 310T) and (345, 355, and 315T) can correspond to the portions of BL₀ and BLB₀ (i.e., BL/BLB in COL₀) operatively coupled to the memory cells 125T in COL₀, respectively.

According to some embodiments of the present disclosure, the BL segments 310B, 315B, 310M, 315M, 310T, and 315T may be disposed, embedded, or otherwise formed in a first one of a plurality of metallization layers formed above a substrate. Such a first metallization layer is sometimes referred to as “M0 layer,” with the metal (e.g., copper) tracks formed therein referred to as “M0 tracks.” Each of the BL segments 310B, 315B, 310M, 315M, 310T, and 315T may be formed as an M0 track extending along a same first lateral direction (e.g., the Y-direction). Moreover, the BL segments 310B, 315B, 310M, 315M, 310T, and 315T are electrically and physically isolated from one another via a dielectric material (e.g., oxide-based dielectric materials or any of various other low-k dielectric materials) of the M0 layer. For example, the BL segments 310B, 310M, and 310T are separated apart from one another along the Y-direction. In some embodiments, the BL segments 310B, 310M, and 310T may be formed around (e.g., above) the memory arrays 120B, 120M, and 120T, respectively. The complementary BL segments 315B, 315M, and 315T may be formed similarly, and thus, the description will not be repeated.

Further, the BL segments 330 and 335 may be disposed, embedded, or otherwise formed in a second one of the metallization layers. Such a second metallization layer is sometimes referred to as “M1 layer,” with the metal (e.g., copper) tracks formed therein referred to as “M1 tracks.” Each of the BL segments 330 and 335 may be formed as an M1 track extending along a same second lateral direction (e.g., the X-direction). The BL segments 320 and 325 may be disposed, embedded, or otherwise formed in a third one of the metallization layers. Such a third metallization layer is sometimes referred to as “M2 layer,” with the metal (e.g., copper) tracks formed therein referred to as “M2 tracks.” Each of the BL segments 320 and 325 may be formed as an M2 track extending along the first lateral direction (e.g., the Y-direction). The BL segments 350 and 355 may be disposed, embedded, or otherwise formed in a fourth one of the metallization layers. Such a fourth metallization layer is sometimes referred to as “M3 layer,” with the metal (e.g., copper) tracks formed therein referred to as “M3 tracks.” Each of the BL segments 350 and 355 may be formed as an M3 track extending along the second lateral direction (e.g., the X-direction). The BL segments 340 and 345 may be disposed, embedded, or otherwise formed in a fifth one of the metallization layers. Such a fifth metallization layer is sometimes referred to as “M4 layer,” with the metal (e.g., copper) tracks formed therein referred to as “M4 tracks.” Each of the BL segments 340 and 345 may be formed as an M4 track extending along the first lateral direction (e.g., the Y-direction).

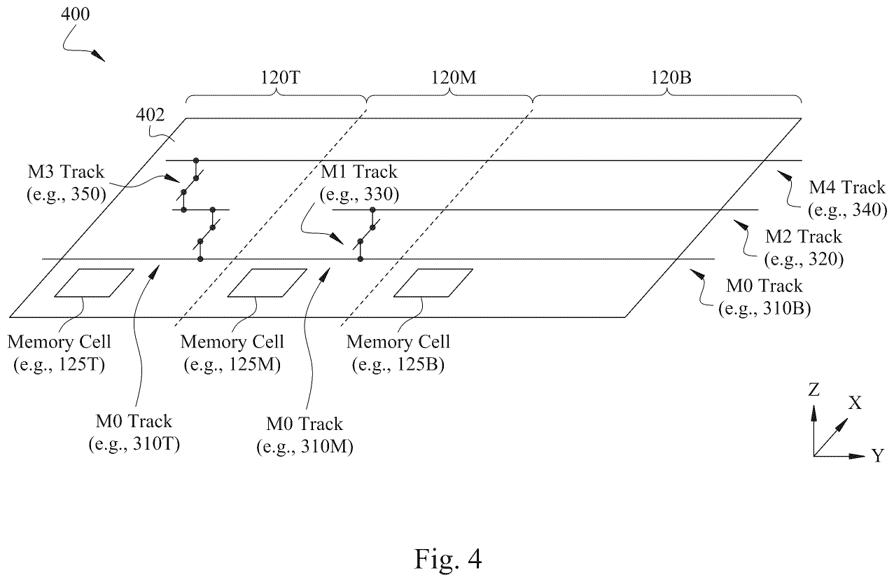

FIG. 4 illustrates a perspective view of a semiconductor device 400 including arrangements of the foregoing components, e.g., the memory cells 125, the metallization layers, M0 to M4 layers, and the metal tracks disposed therein, M0 to M4 tracks, in accordance with some embodiments. It should be appreciated that the arrangements shown in FIG. 4 are merely provided for illustrate a non-limiting implementation of the memory device 100 (shown in FIG. 3), and do not limit the scope of the present disclosure.

As shown, along a major (e.g., frontside) surface of a substrate 402, a plural number of the memory cells 125 can be formed as an array, e.g., over a number of rows (extending in the X-direction) and a number of columns (extending in the Y-direction). The bottom array 120B, the middle array 120M, and the top array 120T may be formed in different lateral areas of the substrate 402, respectively. One memory cell disposed in one of the columns of each corresponding memory array is shown as a representative example in FIG. 4, e.g., 125B, 125M, 125T.

Above the major surface of the substrate 402, a plural number of metallization layers are formed. For example, a number of M0 tracks (e.g., BL segments 310B, 310M, 310T) are disposed in the immediately next upper metallization layer (M0 layer). The M0 tracks may extend along the column direction of the memory array (e.g., the Y-direction). Further above M0 layer, a number of M2 tracks (e.g., BL segment 320) are disposed in M2 layer, with M1 layer interposed therebetween. The M2 tracks may also extend along the column direction of the memory array (e.g., the Y-direction). M1 layer includes one or more M1 tracks (e.g., BL segment 330) coupling at least one of the M2 tracks to a corresponding M0 track. The M1 track may extend along the row direction of the memory array (e.g., the X-direction). Further above M2 layer, a number of M4 tracks (e.g., BL segment 340) are disposed in M4 layer, with M3 layer interposed therebetween. The M4 tracks may also extend along the column direction of the memory array (e.g., the Y-direction). M3 layer includes one or more M3 tracks (e.g., BL segment 350) coupling at least one of the M4 tracks to a corresponding M2 track. The M3 track may extend along the row direction of the memory array (e.g., the X-direction).

By configuring these BL segments in this way, some of the M2 tracks coupled to the middle array 120M may fly over the bottom array 120B, as shown in FIG. 4. As such, these flying M2 tracks can each extend farther than the (e.g., underlying) M0 tracks can along the column direction (the Y-direction). Similarly, some of the M4 tracks coupled to the top array 120T may fly over both of the bottom array 120B and the middle array 120M. As such, these flying M4 tracks can each extend farther than the (e.g., underlying) M0 tracks can along the column direction (the Y-direction). By separating a memory bank into at least three portions (arrays) and coupling to them with BLs disposed in respectively different metallization layers, (e.g., front-end) loads of each of the BLs can be significantly reduced as each BL is operatively coupled to a fewer number of memory cells, while retaining a relatively large size of the memory bank.

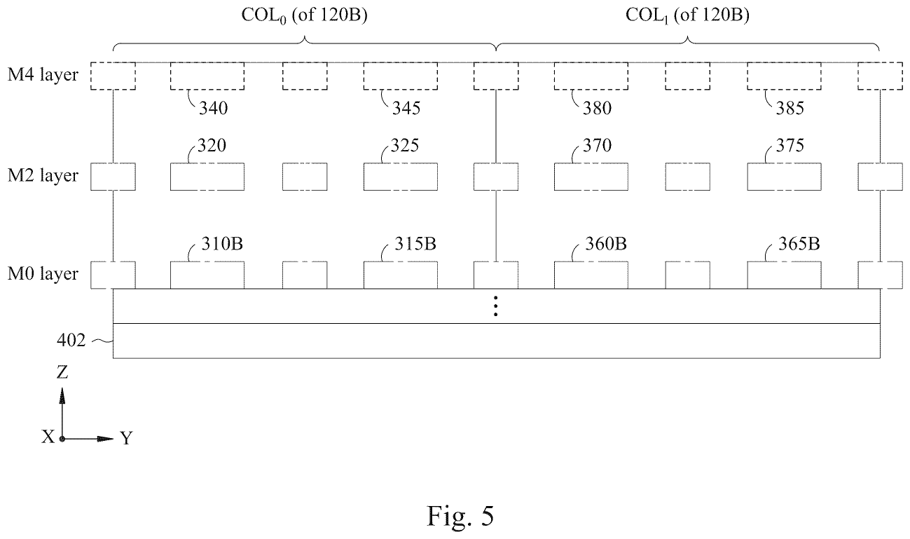

FIG. 5 illustrates an example cross-sectional view of the non-limiting implementation of the memory device 100 (shown in FIGS. 3-4). The cross-sectional view of FIG. 5 is cut along the row direction of the bottom array 120B (e.g., the X-direction) to show two columns, COL₀ and COL₁. It should be appreciated that the cross-sectional view can be similarly extended to other columns, and thus, the description will not be repeated. As shown, on the frontside of the substrate 402, M0 layer, M2 layer, and M4 layer are formed, with one or more other layers (e.g., a device layer including the front-end memory cells 125 and at least one middle-end connection layer) interposed between M0 layer and the substrate 402.

In M0 layer along COL₀, the BL segments 310B and 315B, corresponding to BL₀ and BLB₀ in COL₀ for the bottom array 120B, are formed. Above M0 layer, the BL segments 320 and 325, corresponding to BL₀ and BLB₀ in COL₀ for the middle array 120M, are formed in M2 layer. Above M2 layer, the BL segments 340 and 345, corresponding to BL₀ and BLB₀ in COL₀ for the top array 120T, are formed in M4 layer. In one aspect of the present disclosure, the BL segment 340 may be disposed directly above the BL segment 320, which may be also disposed directly above the BL segment 310B; and the BL segment 345 may be disposed directly above the BL segment 325, which may be also disposed directly above the BL segment 315B, as shown in FIG. 5. However, it should be understood that the BL segments of BL₀/BLB₀ may not necessarily be vertically aligned with one another, while remaining within the scope of the present disclosure.

Laterally next to COL₀ (in the Y-direction), BL segments 360B and 365B, corresponding to BL₁ and BLB₁ in COL₁ for the bottom array 120B, are formed in M0 layer. Above M0 layer, BL segments 370 and 375, corresponding to BL₁ and BLB₁ in COL₁ for the middle array 120M, are formed in M2 layer. Above M2 layer, BL segments 380 and 385, corresponding to BL₁ and BLB₁ in COL₁ for the top array 120T, are formed in M4 layer. In one aspect of the present disclosure, the BL segment 380 may be disposed directly above the BL segment 370, which may also be disposed directly above the BL segment 360B; and the BL segment 385 may be disposed directly above the BL segment 375, which may also be disposed directly above the BL segment 365B, as shown in FIG. 5. However, it should be understood that the BL segments of BL₁/BLB₁ may not necessarily be vertically aligned with one another, while remaining within the scope of the present disclosure.

Among each of M0, M2, and M4 layers, a number of other metal tracks can be formed, as shown in FIG. 5. Such metal tracks can each be configured as a portion of a signal line (e.g., transmitting and/or receiving a signal for one or more corresponding memory cells) or a portion of a power rail (e.g., delivering a supply voltage to one or more corresponding memory cells).

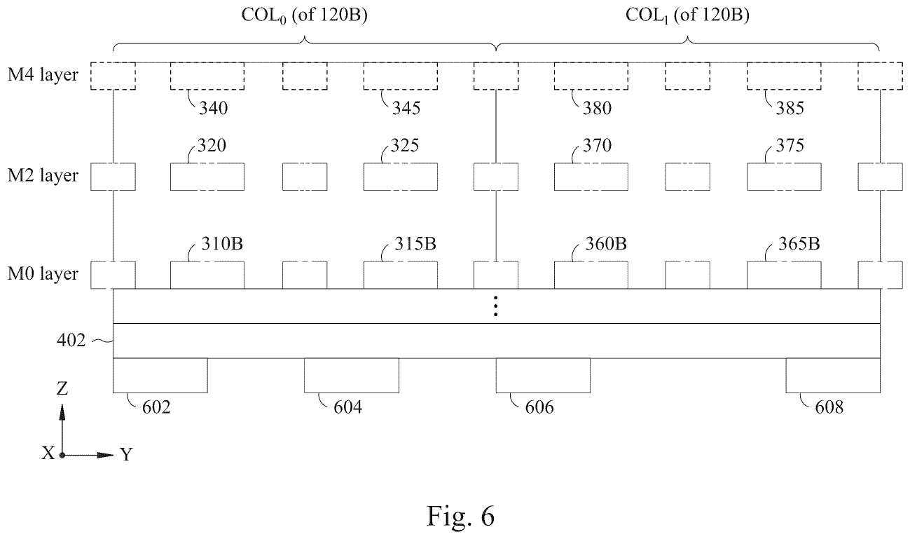

FIG. 6 illustrates another example cross-sectional view of the non-limiting implementation of the memory device 100 (shown in FIGS. 3-4). The cross-sectional view of FIG. 6 is substantially similar to FIG. 5, except that one or more metal tracks are formed on a backside of the substrate 402 in FIG. 6. For example, the cross-sectional view of FIG. 6 further includes metal tracks 602, 604, 606, and 608 disposed on the backside of the substrate 402. Such metal tracks 602 to 608 may each be configured as a power rail to deliver a supply voltage to one or more corresponding memory cells formed on the frontside of the substrate 402.

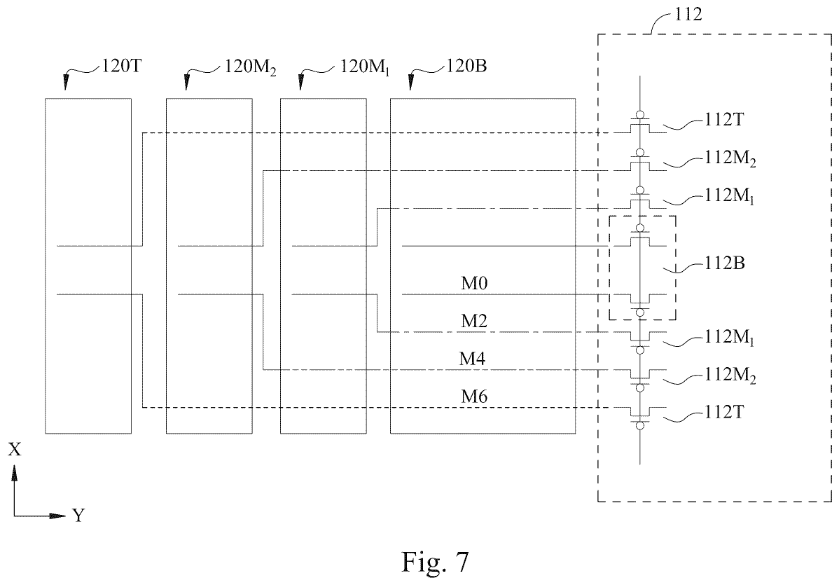

FIG. 7 illustrates a schematic block diagram of another implementation of a portion of the memory device 100, in accordance with some embodiments. For example, in FIG. 7, a portion of the memory bank 120 and a portion of the BL controller 112 are shown. Further, some of the BLs, and their operatively equivalent segments (e.g., each implemented as a metal track disposed in a corresponding metallization layer), are shown. It should be understood that the schematic block diagram of FIG. 7 is merely provided for illustrative purposes, and thus, the memory device 100 can be implemented as any of various other suitable configurations while remaining within the scope of the present disclosure.

As shown, the memory bank 120 may be operatively separated into four arrays, bottom array 120B, first middle array 120M₁, second middle array 120M₂, and top array 120T. In one non-limiting example where the memory bank 120 has 1024 rows (e.g., 1024 WLs), the bottom array 120B may have 512 rows (e.g., 512 WLs), the first middle array 120M₁ may have 256 rows (e.g., 256 WLs), and each of the second middle array 120M2 and top array 120T may have 128 rows (e.g., 128 WLs). However, other arrangement on the respective sizes of the separated arrays can be contemplated while remaining within the scope of the present disclosure. Corresponding to these four separated arrays, respectively, the BL controller 112 may include four sub-BL controllers bottom BL controller 112B, first middle BL controller 112M1, second middle BL controller 112M₂, and top BL controller 112T, which are configured to assert or otherwise select one or more BLs belonging to the arrays 120B, 120M₁, 120M₂, and 120T, respectively, based on an address signal received.

Operatively, the sub-BL controllers, 112B, 112M₁, 112M₂, and 112T, are each coupled to the memory cells 125 of a corresponding separated array through a pair of BLs, BL and BLB, as shown in FIG. 1. In various embodiments, some of these operative BLs and BLBs, flying over one or more memory arrays, may each be physically implemented as one or more lateral segments (e.g., metal tracks) and one or more vertical connections (e.g., via structures) connected to one another. For example in FIG. 7, the sub-BL controller 112B is operatively coupled to the bottom array 120B through a corresponding set of M0 tracks; the sub-BL controller 112M₁ is operatively coupled to the first middle array 120M1 through a corresponding set of M2 tracks; the sub-BL controller 112M₂ is operatively coupled to the second middle array 120M₂ through a corresponding set of M4 tracks; and the sub-BL controller 112T is operatively coupled to the top array 120T through a corresponding set of M6 tracks. In some embodiments, the M2 tracks may each fly over the array 120B to couple to the array 120M1; the M4 tracks may each fly over the arrays 120B and 120M1 to couple to the array 120M2; and the M6 tracks may each fly over the arrays 120B, 120M1, and 120M2 to couple to the array 120T.

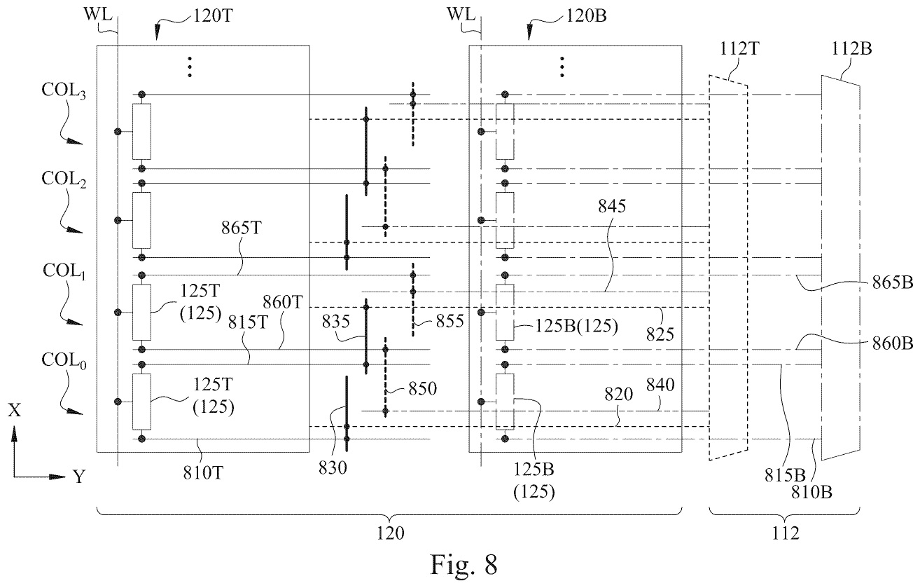

FIG. 8 illustrates a schematic block diagram of yet another implementation of a portion of the memory device 100, in accordance with some embodiments. For example, in FIG. 8, a portion of the memory bank 120 and a portion of the BL controller 112 are shown. Further, some of the BLs, and their operatively equivalent segments (e.g., each implemented as a metal track disposed in a corresponding metallization layer), are shown. It should be understood that the schematic block diagram of FIG. 8 is merely provided for illustrative purposes, and thus, the memory device 100 can be implemented as any of various other suitable configurations while remaining within the scope of the present disclosure.

As shown, the memory bank 120 may be operatively separated into two arrays, bottom array 120B and top array 120T. In one non-limiting example where the memory bank 120 has 1024 rows (e.g., 1024 WLs), the bottom array 120B may have 512 rows (e.g., 512 WLs) and top array 120T may have 512 rows (e.g., 512 WLs). However, other arrangement on the respective sizes of the separated arrays can be contemplated while remaining within the scope of the present disclosure. Corresponding to these two separated arrays, respectively, the BL controller 112 may include two sub-BL controllers, bottom BL controller 112B and top BL controller 112T. In various embodiments, each of the sub-BL controllers 112B and 112T may include at least a multiplexer configured to assert or otherwise select one or more BLs based on an address signal received. Further, each of the sub-BL controllers 112B and 112T may be operatively coupled to the memory cells 125 of the corresponding array (e.g., applying a voltage signal to the memory cells 125) through a respective set of BLs.

Operatively, the sub-BL controllers, 112B and 112T, are each coupled to the memory cells 125 of a corresponding separated array through a pair of BLs, BL and BLB, as shown in FIG. 1. In various embodiments, some of these operative BLs and BLBs, flying over one or more memory arrays, may each be physically implemented as one or more lateral segments (e.g., metal tracks) and one or more vertical connections (e.g., via structures) connected to one another, which will be discussed in further detail below.

As shown in FIG. 8, the memory bank 120 is separated into two arrays along the BL direction (e.g., the Y-direction), while retaining the arrangement along the WL direction (e.g., the X-direction). As such, it should be noted that each of the sub-BL controllers, 112B and 112T, remains coupled to all of the BLs of the memory bank 120, but is just coupled to different subsets of the WLs of the memory bank 120. In the following discussion associated with FIG. 8, examples illustrating the arrangement between the sub-BL controllers, 112B and 112T, and one or more representative columns (e.g., COL₀, COL₁) will be provided. The arrangements between the sub-BL controllers, 112B and 112T, and others column (e.g., COL₂, COL₃) will not be repeated.

For example, the bottom BL controller 112B can be operatively coupled to the memory cells 125 of the bottom array 120B (sometimes referred to as bottom memory cells 125B) in COL₀ through BL segments 810B and 815B; and the top BL controller 112T can be operatively coupled to the memory cells 125 of the top array 120T (sometimes referred to as top memory cells 125T) in COL₀ through BL segments 820 and 825, further through BL segments 830 and 835, and further through BL segments 810T and 815T. Further, the bottom BL controller 112B can be operatively coupled to the memory cells 125 of the bottom memory cells 125B in COL₁ through BL segments 860B and 865B; and the top BL controller 112T can be operatively coupled to the top memory cells 125T in COL₁ through BL segments 840 and 845, further through BL segments 850 and 855, and further through BL segments 860T and 865T.

In some embodiments, the BL segments 810B and 815B can correspond to the portions of BL₀ and BLB₀ (i.e., BL/BLB in COL₀) operatively coupled to the memory cells 125B in COL₀, respectively; the BL segments (820, 830, and 810T) and (825, 835, and 815T) can correspond to the portions of BL₀ and BLB₀ (i.e., BL/BLB in COL₀) operatively coupled to the memory cells 125T in COL₀, respectively; the BL segments 860B and 865B can correspond to the portions of BL₁ and BLB₁ (i.e., BL/BLB in COL₁) operatively coupled to the memory cells 125B in COL₁, respectively; the BL segments (840, 850, and 860T) and (845, 855, and 865T) can correspond to the portions of BL₁ and BLB₁ (i.e., BL/BLB in COL₁) operatively coupled to the memory cells 125T in COL₁, respectively.

According to some embodiments of the present disclosure, the BL segments 810B, 815B, 810T, and 815T may be disposed, embedded, or otherwise formed in M0 layer. Each of the BL segments 810B, 815B, 810T, and 815T may be formed as an M0 track extending along a same first lateral direction (e.g., the Y-direction). Moreover, the BL segments 810B, 815B, 810T, and 815T are electrically and physically isolated from one another via a dielectric material (e.g., oxide-based dielectric materials or any of various other low-k dielectric materials) of the M0 layer. In some embodiments, the BL segments 810B and 810T may be formed around (e.g., above) the memory arrays 120B and 120T, respectively. The complementary BL segments 815B and 815T may be formed similarly, and thus, the description will not be repeated.

Further, the BL segments 830 and 835 may be disposed, embedded, or otherwise formed in Ml layer. Each of the BL segments 830 and 835 may be formed as an M1 track extending along a same second lateral direction (e.g., the X-direction). The BL segments 820 and 825 may be disposed, embedded, or otherwise formed in M2 layer. Each of the BL segments 820 and 825 may be formed as an M2 track extending along the first lateral direction (e.g., the Y-direction). The BL segments 850 and 855 may be disposed, embedded, or otherwise formed in M3 layer. Each of the BL segments 850 and 855 may be formed as an M3 track extending along the second lateral direction (e.g., the X-direction). The BL segments 840 and 845 may be disposed, embedded, or otherwise formed in M4 layer. Each of the BL segments 840 and 845 may be formed as an M4 track extending along the first lateral direction (e.g., the Y-direction).

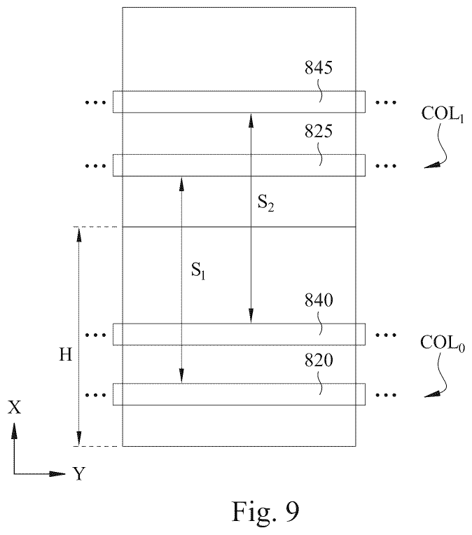

FIG. 9 illustrates an example top view of the BL segments (M2 tracks) 820 and 825 and BL segments (M4 tracks) 840 and 845 across COL₀ and COL₁, in accordance with some embodiments. As shown, the portion of BL₀ operatively coupled to the memory cells 125T in COL₀ (e.g., BL segment 820) and the portion of BLB₀ operatively coupled to the memory cells 125T in COL₀ (e.g., BL segment 825) are separated from each other with a spacing “S₁.” In some embodiments, such a spacing may be laterally offset from the boundary of a memory cell that has a cell height “H.” As such, the BL segment 820 may be disposed along COL₀, and the BL segment 825 may be disposed along COL₁. Alternatively stated, the respective portions of the BL and its corresponding BLB, that are operatively coupled to the farther memory cells (e.g., 125T) in a certain column, are separately disposed in different columns.

Similarly, the portion of BL₁ operatively coupled to the memory cells 125T in COL₁ (e.g., BL segment 840) and the portion of BLB₁ operatively coupled to the memory cells 125T in COL₁ (e.g., BL segment 845) are separated from each other with a spacing “S₂.” In some embodiments, such a spacing may be laterally offset from the boundary of a memory cell that has a cell height “H.” As such, the BL segment 840 may be disposed along COL₀, and the BL segment 845 may be disposed along COL₁. Alternatively stated, the respective portions of the BL and its corresponding BLB, that are operatively coupled to the farther memory cells (e.g., 125T) in a certain column, are separately disposed in different columns.

By configuring these BL segments in this way, some of the M2 tracks can fly over the bottom array 120B to couple to the top (farther) array 120T, as shown in FIG. 8. As such, these flying M2 tracks can each extend farther than the (e.g., underlying) M0 tracks can along the column direction (the Y-direction). Further, these M2 tracks coupled to the farther array can be pushed away from each other along the row direction (the X-direction) with a larger spacing, as shown in FIG. 9. Similarly, some of the M4 tracks can fly over the bottom array 120B to couple to the top (farther) array 120T, as shown in FIG. 8. As such, these flying M4 tracks can each extend farther than the (e.g., underlying) M0 tracks can along the column direction (the Y-direction). Further, these M4 tracks can be pushed away from each other along the row direction (the X-direction) with a larger spacing, as shown in FIG. 9. With such an extended spacing, capacitive coupling between adjacent metal tracks in one or more of the metallization layers can be significantly reduced.

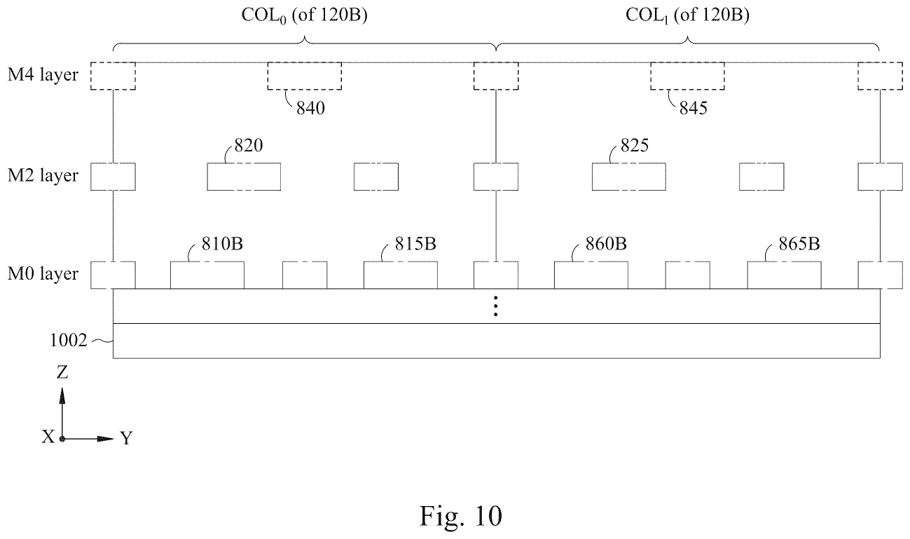

FIG. 10 illustrates an example cross-sectional view of the non-limiting implementation of the memory device 100 (shown in FIGS. 8-9). The cross-sectional view of FIG. 10 is cut along the row direction of the bottom array 120B (e.g., the X-direction) to show two columns, COL₀ and COL₁. It should be appreciated that the cross-sectional view can be extended to other columns, and thus, the description will not be repeated. As shown, on the frontside of a substrate 1002, M0 layer, M2 layer, and M4 layer are formed, with one or more other layers (e.g., a device layer including the front-end memory cells 125 and at least one middle-end connection layer) interposed between M0 layer and the substrate 1002.

In M0 layer, the BL segments 810B and 815B, corresponding to BL₀ and BLB₀ in COL₀ for the bottom array 120B, and the BL segments 860B and 865B, corresponding to BL₁ and BLB₁ in COL₁ for the bottom array 120B are formed. Above M0 layer, the BL segments 820 and 825, corresponding to BL₀ and BLB₀ in COL₀ for the top array 120T, are formed in M2 layer. Above M2 layer, the BL segments 840 and 845, corresponding to BL₁ and BLB₁ in COL₁ for the top array 120T, are formed in M4 layer. In one aspect of the present disclosure, the BL segment 820 may be laterally shifted from any of the BL segment 810B or 815B, and the BL segment 840 may also be laterally shifted from the BL segment 820; and the BL segment 825 may be laterally shifted from any of the BL segment 860B or 865B, and the BL segment 845 may also be laterally shifted from the BL segment 825, as shown in FIG. 10. However, it should be understood that the BL segments of BL₀/BLB₀ and BL₁/BLB₁ may not necessarily be laterally offset from one another, while remaining within the scope of the present disclosure.

Among each of M0, M2, and M4 layers, a number of other metal tracks can be formed, as shown in FIG. 10. Such metal tracks can each be configured as a portion of a signal line (e.g., transmitting and/or receiving a signal for one or more corresponding memory cells) or a portion of a power rail (e.g., delivering a supply voltage to one or more corresponding memory cells).

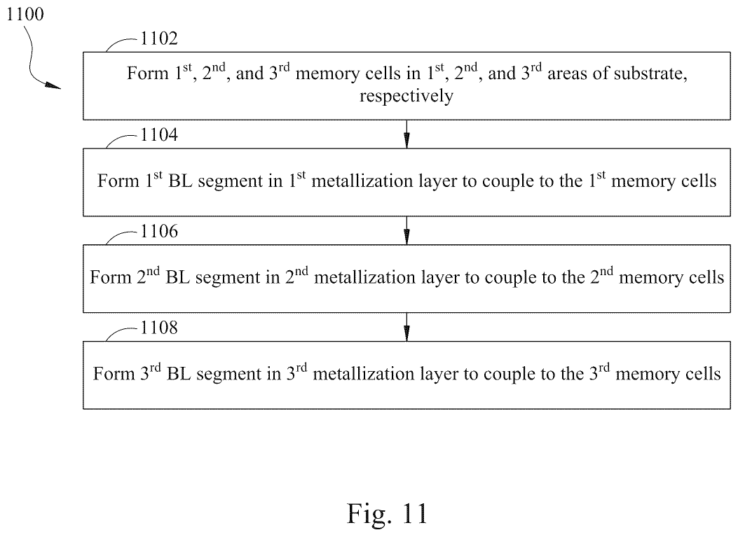

FIG. 11 illustrates a flow chart of an example method 1100 for forming a memory device, in accordance with various embodiments. For example, the method 1100 can be utilized to form the implementation of the memory device 100, as illustrated in FIG. 3. In some embodiments, operations of the method 1100 are performed in the order depicted in FIG. 11. In some other embodiments, operations of the method 1100 may be performed simultaneously and/or in an order other than the order depicted in FIG. 11.

The method 1100 starts with operation 1102 of forming a plurality of first memory cells, a plurality of second memory cells, and a plurality of third memory cells in a first area, a second area, a third area of a substrate, respectively. In some embodiments, the second area is interposed between the first area and the third area along a lateral direction. Further, the first memory cells may correspond to a respective column of memory cells in a first memory array; the second memory cells may correspond to a respective column of memory cells in a second memory array; and the third memory cells may correspond to a respective column of memory cells in a third memory array. As such, the lateral direction corresponds to a column direction of the first to third memory arrays.

Referring again to the implementation of FIG. 3, the first memory cells, the second memory cells, and the third memory cells may be implemented as the bottom memory cells 125B disposed along COL₀, the middle memory cells 120M disposed along COL₀, and the top memory cells 120T disposed along COL₀, respectively.

The substrate may be a wafer, such as a silicon wafer, or a silicon-on-insulator (SOI) substrate. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Each of the first to third memory cells may be implemented as a six-transistor (6T) static random access memory (SRAM) cell that consists of six transistors (e.g., N₁, N₂, N₃, N₄, P₁, and P₂), as shown in FIG. 2. However, it should be understood that the first to third memory cells may be implemented as other type of SRAM configurations than 6T, e.g., eight transistor (8T) or ten transistor (10T) configurations. Alternatively or additionally, the first to third memory cells may be implemented as other type of memory cells such as, for example, dynamic random access memory (DRAM) cells, resistive random access memory (RRAM) cells, phase-change random access memory (PCRAM) cells, or magnetoresistive random access memory (MRAM) cells. In various embodiments, the first to third memory cells may be formed along a major (e.g., frontside) surface of the substrate, that is, all the first to third areas, where the first to third memory cells are respectively formed, being located along such a major surface. According fabrication of these first to third memory cells (and corresponding memory arrays) may sometimes be referred to as front-end-of-line (FEOL) processing.

The method 1100 proceeds to operation 1104 of forming a first bit line segment in a first one of a plurality of metallization layers over the substrate, in which the first bit line segment physically extends along the lateral direction and is operatively coupled to each of the plurality of first memory cells. In some embodiments, the first bit line segment may correspond to the BL and BLB operatively coupled to the first memory cells formed in the first area of the substrate. The first bit line segment can extend along the lateral direction from a corresponding BL controller, which is located immediately next to a first edge of the first area along the lateral direction, through the first area, and toward a second edge of the first area opposite to the first edge. Further, the first bit line segment may be formed in a first one of multiple metallization layers disposed above the substrate.

Continuing with the above example of FIG. 3, the first bit line segment may be implemented as BL segments 310B and 315B. The BL segments 310B and 315B are formed in M0 layer, with a first length extending along the lateral direction (the Y-direction), above the substrate. As such, the BL segments 310B and 315B are operatively coupled to the bottom memory cells 125B disposed along COL₀. M0 layer may sometimes be referred to as a bottommost one of the metallization layers above the substrate. According fabrication of such metallization layers may sometimes be referred to as back-end-of-line (BEOL) processing. The BL segments 310B and 315B can include one or more metal materials such as, for example, tungsten (W), copper (Cu), gold (Au), cobalt (Co), Ruthenium (Ru), or combinations thereof, and be fabricated using one or more damascene processes.

The method 1100 proceeds to operation 1106 of forming a second bit line segment in a second one of the metallization layers that is disposed above the first metallization layer, in which the second bit line segment physically extends along the lateral direction and is operatively coupled to each of the plurality of second memory cells. In some embodiments, the second bit line segment may correspond to the BL and BLB operatively coupled to the second memory cells formed in the second area of the substrate. The second bit line segment can extend along the lateral direction from a corresponding BL controller, which is also located immediately next to the first edge of the first area along the lateral direction, over the first area, toward an edge of the second area facing the second edge of the first area. Further, the second bit line segment may be formed in a second one of multiple metallization layers disposed above the first metallization layer.

Continuing with the above example of FIG. 3, the second bit line segment may be implemented as BL segments 320 and 325. The BL segments 320 and 325 are formed in M2 layer, with a second length extending along the lateral direction (the Y-direction) longer than the first length, above M0 layer. As such, the BL segments 320 and 325 fly over the first area, without operatively coupling to the bottom memory cells 125B disposed along COL₀ but operatively coupling to the middle memory cells 125M along COL₀. The BL segments 320 and 325 can include one or more metal materials such as, for example, tungsten (W), copper (Cu), gold (Au), cobalt (Co), Ruthenium (Ru), or combinations thereof, and be fabricated using one or more damascene processes.

The method 1100 proceeds to operation 1108 of forming a third bit line segment in a third one of the metallization layers that is disposed above the second metallization layer, in which the third bit line segment physically extends along the lateral direction and is operatively coupled to each of the plurality of third memory cells. In some embodiments, the third bit line segment may correspond to the BL and BLB operatively coupled to the third memory cells formed in the third area of the substrate. The third bit line segment can extend along the lateral direction from a corresponding BL controller, which is also located immediately next to the first edge of the first area along the lateral direction, over the first area and second area, toward an edge of the third area facing the other edge of the second area. Further, the third bit line segment may be formed in a third one of multiple metallization layers disposed above the second metallization layer.

Continuing with the above example of FIG. 3, the third bit line segment may be implemented as BL segments 340 and 345. The BL segments 340 and 345 are formed in M4 layer, with a third length extending along the lateral direction (the Y-direction) longer than the second length, above M2 layer. As such, the BL segments 340 and 345 fly over the first and second areas, without operatively coupling to the bottom memory cells 125B or middle memory cells 125M disposed along COL₀ but operatively coupling to the top memory cells 125T along COL₀. The BL segments 340 and 345 can include one or more metal materials such as, for example, tungsten (W), copper (Cu), gold (Au), cobalt (Co), Ruthenium (Ru), or combinations thereof, and be fabricated using one or more damascene processes.

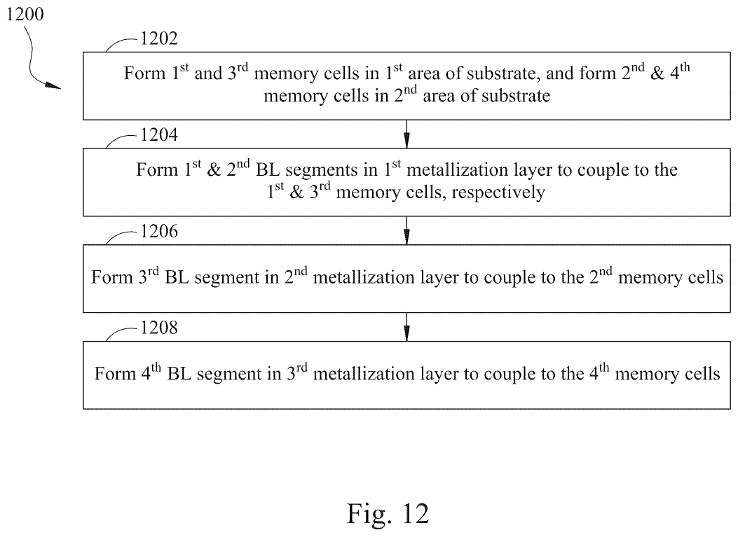

FIG. 12 illustrates a flow chart of an example method 1200 for forming a memory device, in accordance with various embodiments. For example, the method 1200 can be utilized to form the implementation of the memory device 100, as illustrated in FIG. 8. In some embodiments, operations of the method 1200 are performed in the order depicted in FIG. 12. In some other embodiments, operations of the method 1200 may be performed simultaneously and/or in an order other than the order depicted in FIG. 12.

The method 1200 starts with operation 1202 of forming a plurality of first memory cells and a plurality of third memory cells in a first area of a substrate and forming a plurality of second memory cells and a plurality of fourth memory cells in a second area of the substrate. In some embodiments, the second area is disposed next to the first area along a lateral direction. Further, the first memory cells may correspond to a respective column of memory cells in a first memory array; and the second memory cells may correspond to a respective column of memory cells in a second memory array. As such, the lateral direction corresponds to a column direction of the first and second memory arrays. While forming the first to second memory cells, the third memory cells and the fourth memory cells may be concurrently formed in the first area and second area, respectively. The third memory cells may correspond to another respective column of memory cells in the first memory array; and the fourth memory cells may correspond to another respective column of memory cells in the second memory array.

Referring again to the implementation of FIG. 8, the first memory cells and the second memory cells may be implemented as the bottom memory cells 125B disposed along COL₀ and the top memory cells 120T disposed along COL₀, respectively. The third memory cells and the fourth memory cells may be implemented as the bottom memory cells 125B disposed along COL₁ and the top memory cells 120T disposed along COL₁, respectively.

The substrate may be a wafer, such as a silicon wafer, or a silicon-on-insulator (SOI) substrate. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Each of the first to fourth memory cells may be implemented as a six-transistor (6T) static random access memory (SRAM) cell that consists of six transistors (e.g., N₁, N₂, N₃, N₄, P₁, and P₂), as shown in FIG. 2. However, it should be understood that the first to fourth memory cells may be implemented as other type of SRAM configurations than 6T, e.g., eight transistor (8T) or ten transistor (10T) configurations. Alternatively or additionally, the first to fourth memory cells may be implemented as other type of memory cells such as, for example, dynamic random access memory (DRAM) cells, resistive random access memory (RRAM) cells, phase-change random access memory (PCRAM) cells, or magnetoresistive random access memory (MRAM) cells. In various embodiments, the first to fourth memory cells may be formed along a major (e.g., frontside) surface of the substrate, that is, all the first and second areas, where the first to fourth memory cells are respectively formed, being located along such a major surface. According fabrication of these first to fourth memory cells (and corresponding memory arrays) may sometimes be referred to as front-end-of-line (FEOL) processing.

The method 1200 proceeds to operation 1204 of forming a first bit line segment and a second bit line segment in a first one of a plurality of metallization layers over the substrate, in which the first and second bit line segments each physically extend along the lateral direction and are operatively coupled to each of the plurality of first memory cells and each of the plurality of third memory cells, respectively. In some embodiments, the first bit line segment may correspond to the BL and BLB operatively coupled to the first memory cells formed in the first area of the substrate, and the second bit line segment may correspond to the BL and BLB operatively coupled to the third memory cells formed in the first area of the substrate. The first and second bit line segments can each extend along the lateral direction from a corresponding BL controller, which is located immediately next to a first edge of the first area along the lateral direction, over the first area, and toward a second edge of the first area opposite to the first edge. Further, the first and second bit line segments may be formed in a first one of multiple metallization layers disposed above the substrate.

Continuing with the above example of FIG. 8, the first bit line segment may be implemented as BL segments 810B and 815B, and the second bit line segment may be implemented as BL segments 860B and 865B. The BL segments 810B, 815B, 860B, and 865B are formed in M0 layer, with a first length extending along the lateral direction (the Y-direction), above the substrate. As such, the BL segments 810B and 815B are operatively coupled to the bottom memory cells 125B disposed along COL₀, and the BL segments 860B and 865B are operatively coupled to the bottom memory cells 125B disposed along COL₁. M0 layer may sometimes be referred to as a bottommost one of the metallization layers above the substrate. According fabrication of such metallization layers may sometimes be referred to as back-end-of-line (BEOL) processing. The BL segments 810B, 815B, 860B, and 865B can include one or more metal materials such as, for example, tungsten (W), copper (Cu), gold (Au), cobalt (Co), Ruthenium (Ru), or combinations thereof, and be fabricated using one or more damascene processes.

The method 1200 proceeds to operation 1206 of forming a third bit line segment in a second one of the metallization layers over the substrate, in which the third bit line segment physically extends along the lateral direction and is operatively coupled to each of the plurality of second memory cells. In some embodiments, the third bit line segment may correspond to the BL and BLB operatively coupled to the third memory cells formed in the second area of the substrate. The third bit line segment can extend along the lateral direction from a corresponding BL controller, which is located immediately next to the first edge of the first area along the lateral direction, over the first area, and toward an edge of the second area facing the second edge of the first area. Further, the third bit line segment may be formed in a second one of the multiple metallization layers disposed above the first metallization layer.

Continuing with the above example of FIG. 8, the third bit line segment may be implemented as BL segments 820 and 825. The BL segments 820 and 825 are formed in M2 layer, with a second length extending along the lateral direction (the Y-direction) longer than the first length, above M0 layer. As such, the BL segments 820 and 825 fly over the first area, without operatively coupling to the bottom memory cells 125B disposed along COL₀ or COL₁ but operatively coupling to the middle memory cells 125M along COL₀. Stated another way, the BL segment 820 flies over the bottom memory cells 125B along COL₀ to couple to the top memory cells 125T along COL₀, and the BL segment 825 flies over the bottom memory cells 125B along COL₁ to couple to the top memory cells 125T along COL₀. The BL segments 820 and 825 can include one or more metal materials such as, for example, tungsten (W), copper (Cu), gold (Au), cobalt (Co), Ruthenium (Ru), or combinations thereof, and be fabricated using one or more damascene processes.

The method 1200 proceeds to operation 1208 of forming a fourth bit line segment in a third one of the metallization layers over the substrate, in which the fourth bit line segment physically extend along the lateral direction and is operatively coupled to each of the plurality of fourth memory cells. In some embodiments, the fourth bit line segment may correspond to the BL and BLB operatively coupled to the fourth memory cells formed in the second area of the substrate. The fourth bit line segment can extend along the lateral direction from a corresponding BL controller, which is located immediately next to the first edge of the first area along the lateral direction, over the first area, and toward an edge of the second area facing the second edge of the first area. Further, the fourth bit line segment may be formed in a third one of the multiple metallization layers disposed above the second metallization layer.

Continuing with the above example of FIG. 8, the fourth bit line segment may be implemented as BL segments 840 and 845. The BL segments 840 and 845 are formed in M4 layer, with a third length extending along the lateral direction (the Y-direction) longer than the first length, above M3 layer. As such, the BL segments 840 and 845 fly over the first area, without operatively coupling to the bottom memory cells 125B disposed along COL₀ or COL₁ but operatively coupling to the middle memory cells 125M along COL₁. Stated another way, the BL segment 840 flies over the bottom memory cells 125B along COL₀ to couple to the top memory cells 125T along COL₁, and the BL segment 845 flies over the bottom memory cells 125B along COL₁ to couple to the top memory cells 125T along COL₁. The BL segments 840 and 845 can include one or more metal materials such as, for example, tungsten (W), copper (Cu), gold (Au), cobalt (Co), Ruthenium (Ru), or combinations thereof, and be fabricated using one or more damascene processes.

In one aspect of the present disclosure, a memory device is disclosed. The memory device includes a first memory array comprising a plurality of first memory cells arranged along a corresponding one of a plurality of first columns and respectively across a plurality of first rows, wherein each of the plurality of first columns extends along a first lateral direction and each of the plurality of first rows extends along a second lateral direction. The memory device includes a first bit line segment extending along the first lateral direction and operatively coupled to each of the plurality of first memory cells, wherein the first bit line segment is disposed in a first one of a plurality of metallization layers above the plurality of first memory cells. The memory device includes a second bit line segment extending also along the first lateral direction but operatively isolated from any of the plurality of first memory cells, wherein the second bit line segment is disposed in a second one of the plurality of metallization layers. The memory device includes a third bit line segment extending also along the first lateral direction but operatively isolated from any of the plurality of first memory cells, wherein the third bit line segment is disposed in a third one of the plurality of metallization layers. The first bit line segment has a first length along the first lateral direction, the second bit line segment has a second length along the first lateral direction, and the third bit line segment has a third length along the first lateral direction, and wherein the first length is less than the second length and the second length is less than the third length.

In another aspect of the present disclosure, a memory device is disclosed. The memory device includes a first memory array comprising a plurality of first memory cells disposed along a lateral direction; a second memory array comprising a plurality of second memory cells disposed along the lateral direction; a third memory array comprising a plurality of third memory cells disposed along the lateral direction, wherein the second memory array is interposed between the first memory array and the third memory array along the lateral direction; a first bit line segment extending along the lateral direction and operatively coupled to each of the plurality of first memory cells; a second bit line segment extending along the lateral direction and operatively coupled to each of the plurality of second memory cells; and a third bit line segment extending along the lateral direction and operatively coupled to each of the plurality of third memory cells. The first bit line segment is formed in a first metallization layer, the second bit line segment is formed in a second metallization layer above the first metallization layer, and the third bit line segment is formed in a third metallization layer above the second metallization layer.

In yet another aspect of the present disclosure, a method for forming a memory device is disclosed. The method includes forming a plurality of first memory cells, a plurality of second memory cells, and a plurality of third memory cells in a first area, a second area, a third area of a substrate, respectively, wherein the second area is interposed between the first area and the third area along a lateral direction. The method includes forming a first bit line segment in a first one of a plurality of metallization layers over a first surface of the substrate, the first bit line segment physically extending along the lateral direction and operatively coupled to each of the plurality of first memory cells. The method includes forming a second bit line segment in a second one of the plurality of metallization layers that is disposed above the first metallization layer, the second bit line segment physically extending along the lateral direction and operatively coupled to each of the plurality of second memory cells. The method includes forming a third bit line segment in a third one of the plurality of metallization layers that is disposed above the second metallization layer, the third bit line segment physically extending along the lateral direction and operatively coupled to each of the plurality of third memory cells.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array comprising a plurality of memory cells arranged along a corresponding one of a plurality of columns and respectively across a plurality of rows, wherein each of the plurality of columns extends along a first lateral direction and each of the plurality of rows extends along a second lateral direction;
a bit line controller configured to read data or write data to each of the plurality of memory cells;
a first bit line segment extending along the first lateral direction and disposed in a first metallization layer above the plurality of memory cells, the first bit line segment operatively coupled to the plurality of memory cells;
a second bit line segment extending along the first lateral direction and disposed in a second metallization layer, the second bit line segment operatively coupled to the bit line controller;
a third bit line segment extending along the second lateral direction and disposed in a third metallization layer, the third bit line segment operatively coupled to the first bit line segment and the second bit line segment.

2. The memory device of claim 1, wherein the first bit line segment has a first length along the first lateral direction and the second bit line segment has a second length along the first lateral direction, and wherein the first length is less than the second length.

3. The memory device of claim 1, wherein the second metallization layer is disposed above the first metallization layer and the third metallization layer is disposed between the first metallization layer and the second metallization layer.

4. The memory device of claim 1, wherein the memory array is a first memory array comprising a plurality of first memory cells, the plurality of columns are a plurality of first columns, and the plurality of rows are a plurality of first rows, further comprising:
a second memory array comprising a plurality of second memory cells arranged along a corresponding one of a plurality of second columns and respectively across a plurality of second rows, wherein each of the plurality of second columns extends along the first lateral direction and each of the plurality of second rows extends along the second lateral direction.

5. The memory device of claim 4, wherein the corresponding columns along which the plurality of first memory cells are disposed and the corresponding columns along which the plurality of second memory cells are disposed are aligned with one another in the first lateral direction.

6. The memory device of claim 4, further comprising:
a fourth bit line segment extending along the first lateral direction and disposed in the first metallization layer above the plurality of second memory cells, the fourth bit line segment operatively coupled to the plurality of second memory cells and the bit line controller.

7. The memory device of claim 6, wherein the bit line controller comprises a first bit line sub-controller configured to read data and write data to the plurality of first memory cells and a second bit line sub-controller configured to read data and write data to the plurality of second memory cells.

8. The memory device of claim 7, wherein the second bit line segment is operatively coupled to the first bit line sub-controller and the fourth bit line segment is operatively coupled to the second bit line sub-controller.

9. The memory device of claim 1, further comprising:
a first complementary bit line segment extending along the first lateral direction and disposed in the first metallization layer above the plurality of memory cells, the first complementary bit line segment operatively coupled to the plurality of memory cells;
a second complementary bit line segment extending along the first lateral direction and disposed in the second metallization layer disposed above the first metallization layer, the second complementary bit line segment operatively coupled to the bit line controller;
a third complementary bit line segment extending along the second lateral direction and disposed in the third metallization layer disposed between the first metallization layer and the second metallization layer, the third complementary bit line segment operatively coupled to the first complementary bit line segment and the second complementary bit line segment.

10. The memory device of claim 9, wherein the first complementary bit line segment is complementary to the first bit line segment, the second complementary bit line segment is complementary to the second bit line segment, and the third complementary bit line segment is complementary to the third bit line segment.

11. A memory device, comprising:
a memory array comprising a plurality of memory cells disposed along a first lateral direction;
a bit line controller configured to read data or write data to each of the plurality of memory cells;
a first bit line segment extending along the first lateral direction and disposed in a first metallization layer above the plurality of memory cells, the first bit line segment operatively coupled to the plurality of memory cells;
a second bit line segment extending along the first lateral direction and disposed in a second metallization layer, the second bit line segment operatively coupled to the bit line controller;
a third bit line segment extending along a second lateral direction perpendicular to the first lateral direction and disposed in a third metallization layer, the third bit line segment operatively coupled to the first bit line segment and the second bit line segment.

12. The memory device of claim 11, wherein the first bit line segment has a first length along the first lateral direction and the second bit line segment has a second length along the first lateral direction, and wherein the first length is less than the second length.

13. The memory device of claim 11, wherein the second metallization layer is disposed above the first metallization layer and the third metallization layer is disposed between the first metallization layer and the second metallization layer.

14. The memory device of claim 11, wherein the memory array is a first memory array comprising a plurality of first memory cells disposed along the first lateral direction, further comprising:
a second memory array comprising a plurality of second memory cells disposed along the second lateral direction.

15. The memory device of claim 14, further comprising:
a fourth bit line segment extending along the first lateral direction and disposed in the first metallization layer above the plurality of second memory cells, the fourth bit line segment operatively coupled to the plurality of second memory cells and the bit line controller.

16. The memory device of claim 15, wherein the bit line controller comprises a first bit line sub-controller configured to read data and write data to the plurality of first memory cells and a second bit line sub-controller configured to read data and write data to the plurality of second memory cells.

17. The memory device of claim 16, wherein the second bit line segment is operatively coupled to the first bit line sub-controller and the fourth bit line segment is operatively coupled to the second bit line sub-controller.

18. The memory device of claim 11, further comprising:
a first complementary bit line segment extending along the first lateral direction and disposed in the first metallization layer above the plurality of memory cells, the first complementary bit line segment operatively coupled to the plurality of memory cells;
a second complementary bit line segment extending along the first lateral direction and disposed in the second metallization layer disposed above the first metallization layer, the second complementary bit line segment operatively coupled to the bit line controller;
a third complementary bit line segment extending along the second lateral direction and disposed in the third metallization layer disposed between the first metallization layer and the second metallization layer, the third complementary bit line segment operatively coupled to the first complementary bit line segment and the second complementary bit line segment.

19. The memory device of claim 18, wherein the first complementary bit line segment is complementary to the first bit line segment, the second complementary bit line segment is complementary to the second bit line segment, and the third complementary bit line segment is complementary to the third bit line segment.

20. A memory device, comprising:
a plurality of memory cells;
a bit line controller;
a first bit line segment extending along a first lateral direction and disposed in a first metallization layer above the plurality of memory cells, the first bit line segment operatively coupled to the plurality of memory cells;
a second bit line segment extending along the first lateral direction and disposed in a second metallization layer, the second bit line segment configured to operatively coupled to the bit line controller; and
a third bit line segment extending along a second lateral direction perpendicular to the first lateral direction and disposed in a third metallization layer, the third bit line segment operatively coupled to the first bit line segment and the second bit line segment.
